(19) United States
(12) Patent Application Publication
(10) Pub. No.: US 2012/0061789 A1
(43) Pub. Date: Mar. 15, 2012

(54) IMAGE SENSOR WITH IMPROVED NOISE SHIELDING

(75) Inventors: Zheng Yang, San Jose, CA (US); Zhengyu Li, San Jose, CA (US); Tiejun Dai, Santa Clara, CA (US); Yin Qian, Milpitas, CA (US)

(73) Assignee: OMNIVISION TECHNOLOGIES, INC., Santa Clara, CA (US)

(21) Appl. No.: 12/880,916

(22) Filed: Sep. 13, 2010

(51) Int. Cl. H01L 27/146; H01L 31/18

(52) U.S. Cl. 257/443; 438/73; 257/E27.13; 257/E31.001

(57) ABSTRACT

An image sensor includes a device wafer including a pixel array for capturing image data bonded to a carrier wafer. Signal lines are disposed adjacent to a side of the carrier wafer opposite the device wafer and a metal noise shielding layer is disposed beneath the pixel array within at least one of the device wafer or the carrier wafer to shield the pixel array from noise emanating from the signal lines. A through-silicon-via (“TSV”) extends through the carrier wafer and the metal noise shielding layer and extends into the device wafer to couple to circuitry within the device wafer. Further noising shielding may be provided by highly doping the carrier wafer and/or overlaying the bottom side of the carrier wafer with a low-K dielectric material.

### TECHNICAL FIELD

This disclosure relates generally to image sensors, and in particular but not exclusively, relates to reducing noise in image sensors.

### BACKGROUND INFORMATION

As complementary metal-oxide semiconductor (“CMOS”) image sensors continue to get smaller and faster, switching noise becomes increasingly problematic. Switching noise can be of particular concern to image sensors packaged in through-silicon vias (“TSV”) technology. With such packages, a number of traces or signal lines are laid out on the bottom side of the package. These traces often connect vias on the outer perimeter to solder balls (pins) in the inner region. During sensor operation, if a pin switches rapidly between high low states, and its corresponding trace runs underneath a sensitive part of the image sensor (e.g., pixel array), then a switching noise may be coupled into the image sensor circuitry. This coupled noise may degrade the quality or increase noise in the output image data. The noise contributed from a pin depends on the location of the trace, the run length below the image sensor, the frequency of the switching, and the current in the trace. However, the noise emanating from these traces can affect a portion of the image sensor and even potentially the whole image sensor. This noise problem is more prominent in TSV packaged sensors, due to the relative proximity between the traces and the image sensor circuitry.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 is a cross-sectional view of an image sensor having a highly doped carrier wafer to shield against switching noise, in accordance with an embodiment of the invention.

FIG. 2 is a cross-sectional view of an image sensor including a metal noise shielding layer disposed within the carrier wafer to shield against switching noise, in accordance with an embodiment of the invention.

FIG. 3 is a cross-sectional view of an image sensor including a metal noise shielding layer disposed within the device wafer to shield against switching noise, in accordance with an embodiment of the invention.

FIG. 4 is a flow chart illustrating methods of forming a through-silicon via through the metal noise shielding layer, in accordance with an embodiment of the invention.

FIG. 5 is a cross-sectional view of an image sensor including a low-K dielectric material disposed on the bottom side of a carrier wafer to reduce the coupling capacitance of switching noise, in accordance with an embodiment of the invention.

FIG. 6 is a functional block diagram illustrating an imaging system, in accordance with an embodiment.

FIG. 7 is a circuit diagram illustrating pixel circuitry of two 4T pixels within an imaging system, in accordance with an embodiment.

### DETAILED DESCRIPTION

Embodiments of a system and method for reducing the penetration of switching noise into the circuitry of an image sensor are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

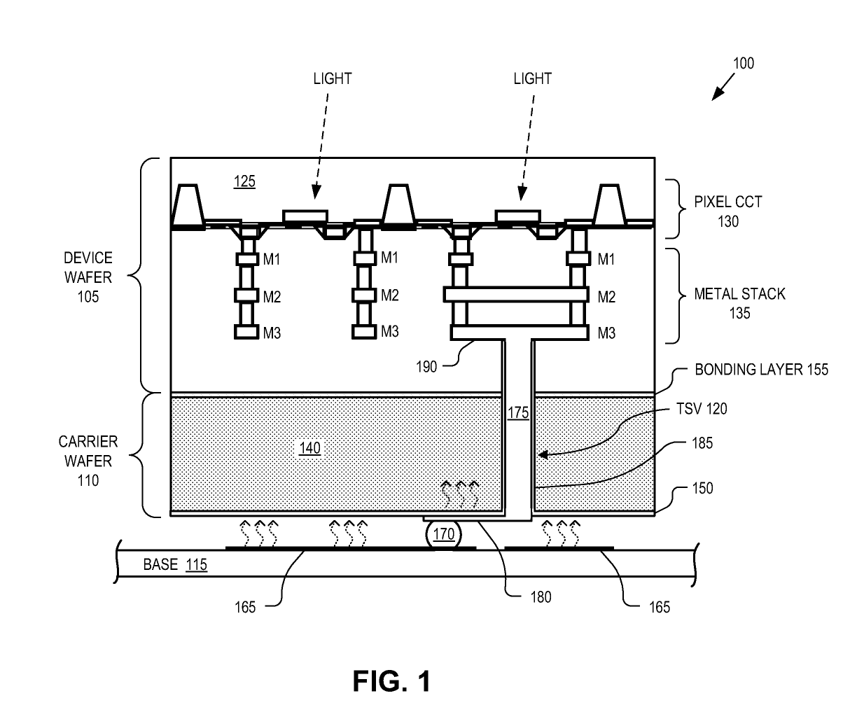

FIG. 1 is a cross-sectional view of an image sensor 100 having a highly doped carrier wafer to shield against switching noise, in accordance with an embodiment of the invention. The illustrated embodiment of image sensor 100 includes a device wafer 105, a carrier wafer 110, a base 115, and a through-silicon via (“TSV”) 120 extending through carrier wafer 110 into device wafer 105. The illustrated embodiment of device wafer 105 includes a semiconductor substrate layer 125, pixel circuitry 130, and a metal stack 135. The illustrated embodiment of carrier wafer 110 includes a highly doped semiconductor substrate 140 and a bottom side insulating layer 150. Device wafer 105 and carrier wafer 110 are fused or bonded together with a bonding layer 155. The illustrated embodiment of base 115 includes signal lines 165, and solder balls or pins 170 coupling base 115 to carrier wafer 110. The illustrated embodiment of TSV 120 includes a metal post 175, metal signal line/pad 180, and insulated sidewall liner 185. The illustrated embodiment of metal stack 135 includes multiple metal layers (e.g., M1, M2, M3) insulated by inter-metal dielectric layers and a metal pad 190 for coupling to TSV 120.

In one embodiment, image sensor 100 is a backside illuminated (“BSI”) complementary metal-oxide semiconductor (“CMOS”) image sensor. Image sensor 100 receives light from the topside of FIG. 1 through substrate layer 125, which is often referred to as the backside of the image sensor, since the side facing metal stack 135 is conventionally referred to as the frontside. However, for the purposes of this disclosure, orientation references such as “top”, “bottom”, “over”, or “under” will be made with respect to the orientation of the specific drawings with the top of the drawings being the “top” and the bottom of the drawings being the “bottom.”

Pixel circuitry 130 (e.g., photo-sensors, transfer transistors, reset transistors, source following transistors, floating diffusions, P-wells, etc.) is disposed in or on substrate layer 125. Substrate layer 125 may be fabricated as an epitaxial silicon layer grown from a bulk substrate layer, which in some embodiments is thinned away. Metal stack 135 includes multiple metal layers (e.g., M1, M2, M3, etc.). These metal layers carry signals under the pixel array and even couple to signal line 180 through metal post 175. Device wafer 105 is chemically bonded to carrier wafer 110 using bonding layer 115. In one embodiment, bonding layer 155 is an oxide layer thereby forming an SiO₂ to Si bonding interface. Carrier wafer 110 is bonded to device wafer 105 to provide mechanical support to the often fragile structure of device wafer 105 (particularly during the backside thinning process). Bottom side insulating layer 150 is disposed on the underside of carrier wafer 110 to insulate signal lines 180 from semiconductor substrate 140. Solder balls/pins 170 couple to signal lines 165 on the base 115.

As discussed above, during operation signal lines 165 and 180 conduct switching signals that can emit electromagnetic (“EM”) noise. This noise can penetrate through carrier wafer 110 into device wafer 105 and adversely affect the operation of pixel circuitry 130 and ultimately the quality of the output images. Some pins and/or signal lines 165 or signal lines 180 can emit more EM noise than others. The frequency of the switching signals these elements conduct, their proximity to susceptible components, their current, and the lengths of their traces can affect the emanation of EM noise. Several techniques have been considered or attempted to address this EM noise. Option A) includes rearranging package pins so that noisy pins have shorter traces and lie on the outer perimeter of the package, away from the region of device wafer 105 that contains sensitive circuitry. This technique was considered to have limited effectiveness. Option B) includes revising the timing sequence of the image sensor so that the operation of the noise-inducing pins occurs in a time when the sensor is less sensitive to EM noise. This technique can sacrifice the frame rate of the image sensor. Option C) includes using the bottom most metal layer within metal stack 135 (e.g., M3 in FIG. 1) as a noise shield. This technique was determined to have little or no improvement in noise immunity and sacrifices a metal interconnect layer. Option D) includes increasing the thickness of carrier wafer 110, which separates the noisy traces from the pixel circuitry 130. This technique was determined to have some potential success; however, packaging requirements limit the maximum thickness to which carrier wafer 110 can be increased, thus limiting its potential.

Accordingly, in the illustrated embodiment, carrier wafer 110 is highly doped to increase its conductivity thereby improving its EM noise absorption properties. Conventional carrier wafers have a linear resistance or resistivity of 5 to 11 ohm-centimeters. In contrast, semiconductor substrate layer 140 of carrier wafer 110 is doped to have a resistivity of less than 5 ohm-centimeters. In one embodiment, semiconductor substrate layer 140 is doped to have a resistivity of less than 0.02 ohm-centimeters. In one embodiment, substrate layer 140 is doped to have a resistivity of 0.01 to 0.02 ohm-centimeters. In one embodiment, substrate layer 140 is doped to have a lower resistivity than substrate layer 125 of device wafer 105. Carrier wafer 110 can be p type or n type doped. Carrier wafer 110 may be made as thick as the constraints of the package will permit.

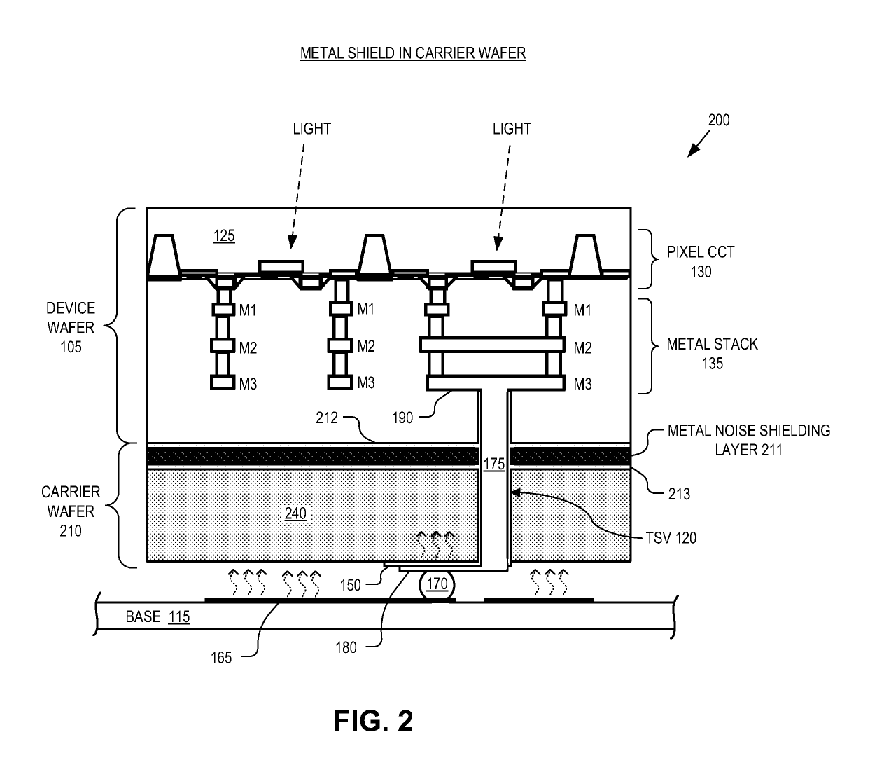

FIG. 2 is a cross-sectional view of an image sensor 200 including a metal noise shielding layer disposed within a carrier wafer to shield against switching noise, in accordance with an embodiment of the invention. Image sensor 200 is similar to image sensor 100, except that carrier wafer 210 may or may not have a highly dope substrate layer 240 and includes a metal noise shielding layer 211 and insulating layers 212 and 213 surrounding metal noise shielding layer 211 to insulate it from substrate layer 240.

In the illustrated embodiment, metal noise shielding layer 211 is disposed on the top surface of carrier wafer 210 at the interface between carrier wafer 210 and device wafer 105. In this configuration, insulating layer 212 can also function as a bonding oxide layer. In one embodiment, both insulating layers 212 and 213 are oxide layers, thereby forming an SiO₂ to SiO₂ bonding interface between the wafers. In other embodiments (not illustrated), metal noise shielding layer 211 maybe be disposed in the interior region of carrier wafer 210 and may even include multiple metal noise shielding layers (e.g., one of the top and one on the bottom of carrier wafer 210). To fabricate image sensor 200, device wafer 105 is fabricated separately from carrier wafer 210 (which includes metal noise shielding layer 211) and then the two wafers are chemically bonded at bonding layer 212. Once bonded, TSV 120 is fabricated by etching a hole through carrier wafer 210 including metal noise shielding layer 211 into device wafer 105 down to metal stack 135. The etching process may use multiple etch procedures to etch substrate layer 240, metal noise shielding layer 211, and the insulating/dielectric layers up to metal pad 190. In one embodiment, a nitride layer (not illustrated) is diposed under metal stack 135 below the last metal layer prior to bonding carrier wafer 210 (this is typically referred to as above the upper most metal layer) and delineates the end of metal stack 135.

Metal noise shielding layer 211 is interposed between the noisy signal lines (e.g., signal lines 165 and 180) and pixel circuitry 130 to reduce EM noise penetration. Metal noise shielding layer 211 can be disposed as a solid blanket layer with minimal holes or gaps through which EM noise can bleed. In one embodiment, metal noise shielding layer 211 is electrically floating, thereby operating as a capacitive noise filter (illustrated). In another embodiment, metal noise shielding layer 211 is biased to a fixed potential (e.g., ground), thereby operating as a noise sink.

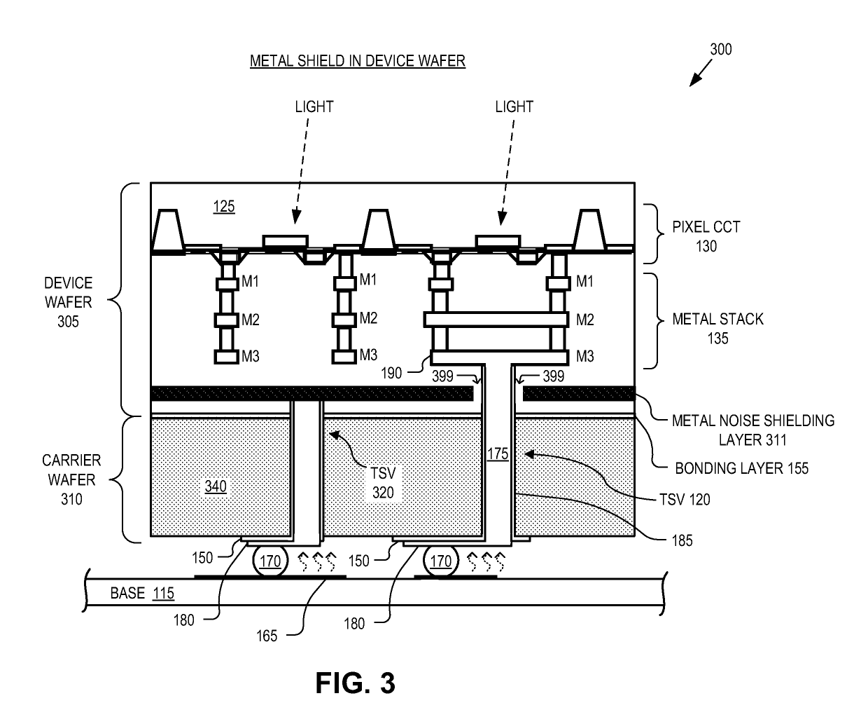

FIG. 3 is a cross-sectional view of an image sensor 300 including a metal noise shielding layer disposed within a device wafer to shield against switching noise, in accordance with an embodiment of the invention. Image sensor 300 is similar to image sensor 200, except that carrier wafer 310 may or may not have a highly dope substrate layer 340, a metal noise shielding layer 311 is disposed in device wafer 305 instead of within carrier wafer 310, and metal noise shielding layer 311 is biased to a fixed potential using TSV 320. TSV 320 may include a similar structure to TSV 120, but terminates at metal noise shielding layer 311, rather than passing through it.

In the illustrated embodiment, metal noise shielding layer 311 is disposed below metal stack 135 and above bonding layer 155. In one embodiment, the material in this region of device wafer 305 may be formed by extending an oxide layer formed on a nitride layer delineating the end of metal stack 135. As such, metal noise shielding layer 311 is already surrounded by insulating material and may not need additional insulating layers such as layers 212 and 213 in FIG. 2. In one embodiment, bonding layer 155 is simply part of this extended oxide layer.

In alternative embodiments, metal noise shielding layer 311 may not be biased to a fixed potential, but rather be electrically floating. In one embodiment, metal noise shielding layer 311 may be disposed in the bottom portion of device wafer 305 and/or metal noise shielding layer 211 may also be incorporated in carrier wafer 310.

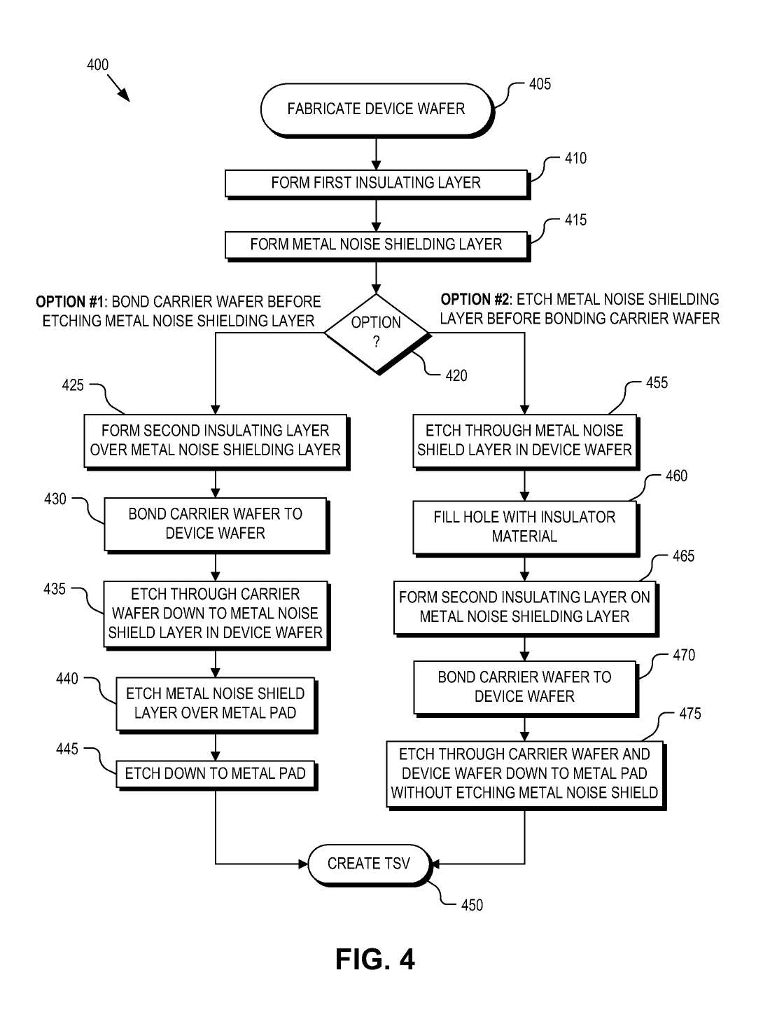

FIG. 4 is a flow chart illustrating methods of forming a TSV in image sensor 300, in accordance with an embodiment of the invention. The order in which some or all of the process blocks appear in process 400 should not be deemed limiting. Rather, one of ordinary skill in the art having the benefit of the present disclosure will understand that some of the process blocks may be executed in a variety of orders not illustrated.

In a process block 405, device wafer 305 is fabricated. This includes forming pixel circuitry 130 in or on substrate layer 125, forming metal stack 135, thinning the light incident side of substrate layer 125, and forming optical layers such as a color filter array and microlenses (not illustrated) over the light incident. In some embodiments, the light incident side may not be thinned until after carrier wafer 310 has been bonded for added rigidity.

In a process block 410, the first insulating layer is formed above (note, prior to bonding the two wafer, the insulating layer would typically be referred to as “below” the metal noise shielding layer) metal noise shielding layer 311. In one embodiment, this insulating layer may be formed by extending the last dielectric layer below metal layer M3 within metal stack 135. In alternative embodiments, a silicon layer may be grown below the last metal layer M3, then a distinct insulating layer formed (not illustrated) for insulating metal noise shielding layer 311. In a process block 415, metal shielding layer 311 is deposited as a blanket metal layer beneath the pixel array. The blanket metal layer may extend under the entire pixel array and peripheral circuitry, just the pixel array, just the peripheral circuitry, or portions thereof.

At this point, fabrication can continue using at least two alternative options (decision block 420). In option #1, carrier wafer 310 is bonded to device wafer 305 prior to etching holes in metal noise shielding layer 311 for TSVs 120. In a process block 425, a second insulating layer is formed on the metal noise shielding layer 311. In one embodiment, the second insulating layer is an oxide layer and serves a dual purpose as the bonding layer between the two wafers. In a process block 430, carrier wafer 310 is chemically bonded to device wafer 305.

Once the two wafers are fused, a first etch forms a hole through carrier wafer 310 into device wafer 305 and stops at metal noise shielding layer 311 (process block 435). A second etchant is used to selectively etch a hole through metal noise shielding layer 311 (process block 440), and a third etch procedure continues the hole to metal pad 190 (process block 445). Finally, in a process block 450, TSV 120 is completed by forming sidewall insulating films 185 and bottom side insulating layer 150, depositing metal post 175, and depositing signal line 180. TSV 320 may be fabricated in a similar manner, except the etching stops are metal noise shielding layer 311.

Returning to decision block 420, option #2 etches a hole through metal noise shielding layer 311 prior to bonding the two wafers. In a process block 455, a hole is etched through noise shielding layer 311 while it is still exposed prior to bonding carrier wafer 310 to device wafer 305. At this stage, only metal noise shielding layer 311 is etched to expose the insulating/dielectric layer upon which metal noise shielding layer 311 is disposed (e.g., this etch procedure need not continue to metal pad 190). In one embodiment, the hole is oversized such that gaps 399 will remain between the outer edges of TSV 120 and metal noise shielding layer 311 (e.g., metal noise shielding layer 311 will not physically contact the outer side of insulated sidewall liner 185.

In a process block 460, the hole is filled with an insulating material. In one embodiment, an oxide is extended through the hole. In a process block 465, the second insulating layer is formed on the exposed underside of metal noise shielding layer 311. In one embodiment, the second insulating layer is a continuation of the insulator filling the gap (e.g., oxide).

In a process block 470, carrier wafer 310 is bonded to device wafer 305. Once the two wafers are fused, the hole for TSV 120 is etched through carrier wafer 310, into device wafer 305, through gaps 399, and down to metal pad 190 (process block 475). Since metal noise shielding layer 311 has already been etched, the TSV etch can be accomplished without having to use a separate etchant for etching metal. Finally, TSV 120 is fabricated in process block 450, as described above.

Fabrication option #2 produces an oversized gap 399 that simplifies the final etch for forming TSV 120, as illustrated in FIG. 3. Fabrication option #1, generates a hole through metal noise shielding layer 211 form fitted to TSV 120 where the insulating sidewall liner abuts the metal noise shielding layer, as illustrated in FIG. 2.

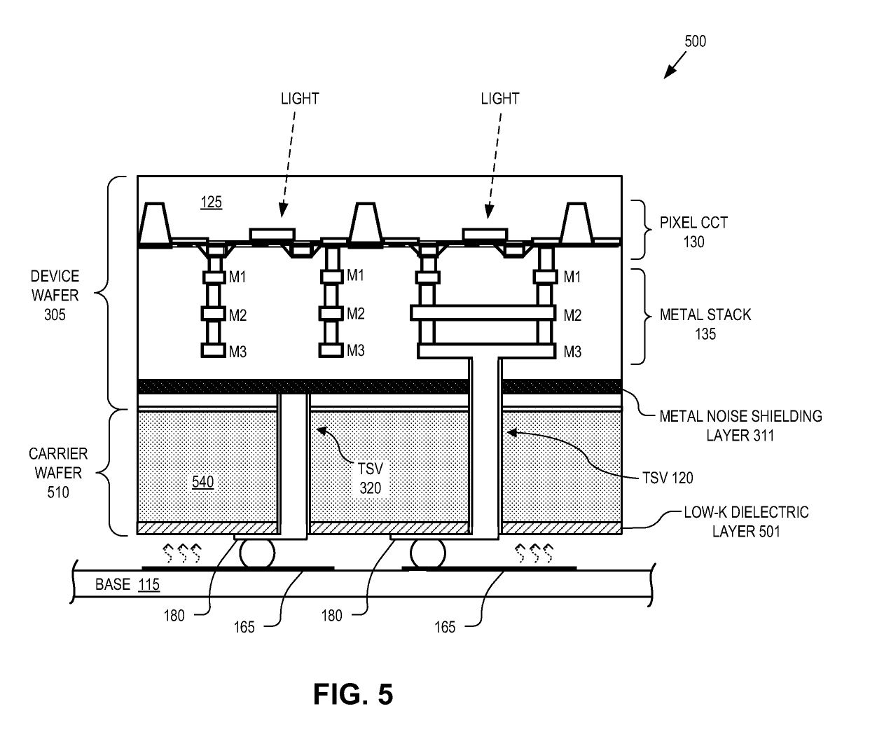

FIG. 5 is a cross-sectional view of an image sensor 500 including a low-K dielectric material disposed on the bottom side of the carrier wafer, in accordance with an embodiment of the invention. Image sensor 500 is similar to image sensor 300, except that carrier wafer 510 includes a low-K dielectric layer 501 disposed over the bottom side of carrier wafer 510 to reduce the coupling capacitance between signal lines 165 and 180 and device wafer 305, thereby reducing the impact of the switching noise. In the illustrated embodiment, low-K dielectric layer 501 may also replace the need for bottom side insulating layer 150 by fabricating signal lines 180 directly on low-K dielectric layer 501. In an alternative embodiment, bottom side insulating layers 150 may still be disposed above/below low-K dielectric layer 501.

Low-K dielectric layer 501 is made of a material having a dielectric constant that is lower than silicon or oxide, such as black diamond. In one embodiment, its dielectric constant is less than 3.0. In one embodiment, substrate layer 540 may be thinned relative to substrate layers 140, 240, or 340 to make head room within the package for low-K dielectric layer 501. In one embodiment, low-K dielectric layer 501 may have a thickness ranging between a few microns to over a hundred microns. Of course, embodiments of substrate layer 540 may optionally be highly doped in a similar manner as substrate layer 140.

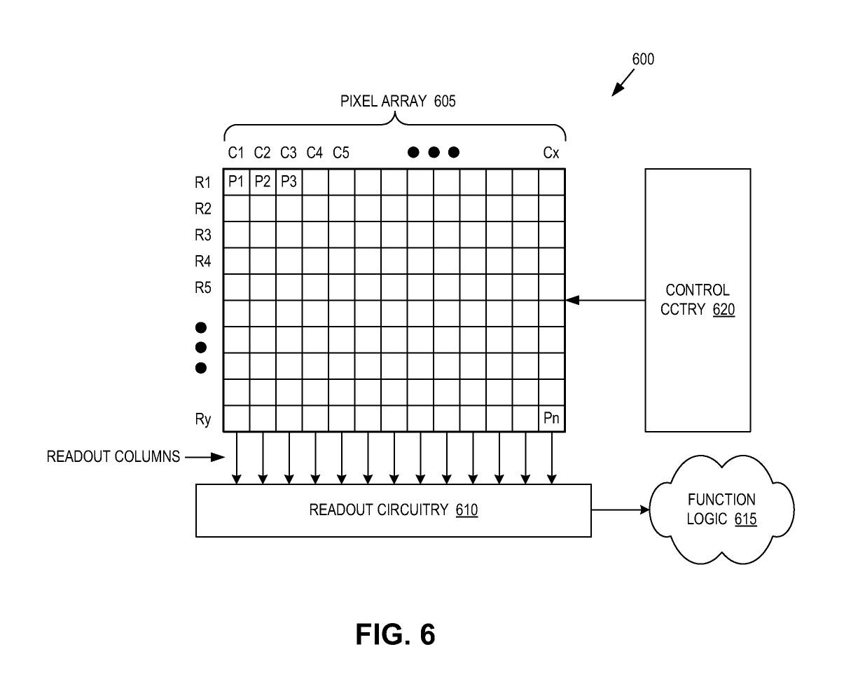

FIG. 6 is a block diagram illustrating an imaging system 600, in accordance with an embodiment of the invention. The illustrated embodiment of imaging system 600 includes a pixel array 605, readout circuitry 610, function logic 615, and control circuitry 620.

Pixel array 605 is a two-dimensional (“2D”) array of imaging sensors or pixels (e.g., pixels P1, P2 . . . , Pn). In one embodiment, each pixel is a complementary metal-oxide-semiconductor (“CMOS”) imaging pixel. The pixels may be implemented as backside illuminated pixels. As illustrated, each pixel is arranged into a row (e.g., rows R1 to Ry) and a column (e.g., column C1 to Cx) to acquire image data of a person, place, or object, which can then be used to render a 2D image of the person, place, or object.

After each pixel has acquired its image data or image charge, the image data is readout by readout circuitry 610 and transferred to function logic 615. Readout circuitry 610 may include amplification circuitry, analog-to-digital (“ADC”) conversion circuitry, or otherwise. Function logic 615 may simply store the image data or even manipulate the image data by applying post image effects (e.g., crop, rotate, remove red eye, adjust brightness, adjust contrast, or otherwise). In one embodiment, readout circuitry 610 may readout a row of image data at a time along readout column lines (illustrated) or may readout the image data using a variety of other techniques (not illustrated), such as a serial readout or a full parallel readout of all pixels simultaneously.

Control circuitry 620 is coupled to pixel array 605 to control operational characteristic of pixel array 605. For example, control circuitry 620 may generate a shutter signal for controlling image acquisition. In one embodiment, the shutter signal is a global shutter signal for simultaneously enabling all pixels within pixel array 605 to simultaneously capture their respective image data during a single acquisition window. In an alternative embodiment, the shutter signal is a rolling shutter signal whereby each row, column, or group of pixels is sequentially enabled during consecutive acquisition windows.

Pixel array 605, readout circuitry 610, and control circuitry 620 may all be disposed in or on a device wafer bonded to a carrier wafer. Thus, one or more of the techniques described above may be used to reduce the above described switching noise from interfering with the image sensor circuitry of the device wafer. As illustrated in FIG. 1, the carrier wafer may be highly doped to reduce noise. As illustrated in FIG. 2, a metal noise shielding layer may be included within the carrier wafer to reduce noise. As illustrated in FIG. 3, the metal noise shielding layer may be disposed within the device wafer below the metal stack to reduce noise. As illustrated in FIG. 5, a low-K dielectric material may be disposed on the bottom of the carrier wafer to reduce capacitive coupling of noise. It should be appreciated that one, some, or all of the above techniques may be used together to provide improved noise immunity from package trace switching noise.

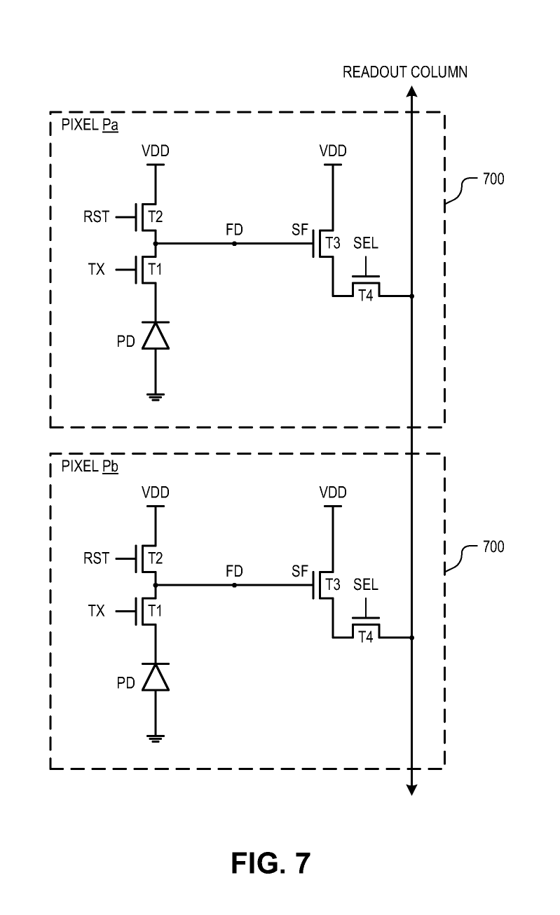

FIG. 7 is a circuit diagram illustrating pixel circuitry 700 of two four-transistor (“4T”) pixels within a pixel array, in accordance with an embodiment of the invention. Pixel circuitry 700 is one possible pixel circuitry architecture for implementing each pixel within pixel array 605 of FIG. 6. However, it should be appreciated that embodiments of the present invention are not limited to 4T pixel architectures; rather, one of ordinary skill in the art having the benefit of the instant disclosure will understand that the present teachings are also applicable to 3T designs, 5T designs, and various other pixel architectures.

In FIG. 7, pixels Pa and Pb are arranged in two rows and one column. The illustrated embodiment of each pixel circuitry 700 includes a photodiode PD, a transfer transistor T1, a reset transistor T2, a source-follower (“SF”) transistor T3 and a select transistor T4. During integration, photodiode PD is exposed to electromagnetic energy and converts the collected electromagnetic energy into electrons. During operation, transfer transistor T1 receives a transfer signal TX, which transfers the charge accumulated in photodiode PD to a floating diffusion node FD. In one embodiment, floating diffusion node FD may be coupled to a storage capacitor for temporarily storing image charges. Reset transistor T2 is coupled between a power rail VDD and the floating diffusion node FD to reset (e.g., discharge or charge the FD to a preset voltage) under control of a reset signal RST. The floating diffusion node FD is coupled to control the gate of SF transistor T3. SF transistor T3 is coupled between the power rail VDD and select transistor T4. SF transistor T3 operates as a source-follower providing a high impedance output from the pixel. Finally, select transistor T4 selectively couples the output of pixel circuitry 700 to the readout column line under control of a select signal SEL.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An image sensor, comprising:
a device wafer having first and second sides, the device wafer including a pixel array for capturing image data in response to light incident on the first side;
a carrier wafer having first and second sides, wherein the first side of the carrier wafer is bonded to the second side of the device wafer;
signal lines disposed adjacent to the second side of the carrier wafer;
a metal noise shielding layer extending beneath the pixel array within at least one of the device wafer or the carrier wafer between the signal lines and the pixel array to shield the pixel array from noise emanating from the signal lines; and
a through-silicon-via (“TSV”) extending from the second side of the carrier wafer, through the carrier wafer and the metal noise shielding layer and extending into the device wafer to couple to circuitry within the device wafer.

2. The image sensor of claim 1, wherein the metal noise shielding layer is disposed within the device wafer and wherein the TSV extends through the metal noise shielding layer to couple to a metal layer disposed within the device wafer between the pixel array and the metal noise shielding layer.

3. The image sensor of claim 2, further comprising another TSV extending from the second side of the carrier wafer through the carrier wafer into the device wafer and couples to the metal noise shielding layer to bias the metal noise shielding layer as a noise sink.

4. The image sensor of claim 1, wherein the metal noise shielding layer comprises an electrically floating capacitive noise filter.

5. The image sensor of claim 1, wherein the metal noise shielding layer is disposed within the carrier wafer.

6. The image sensor of claim 1, further comprising:
first and second insulating layers disposed on either side of the metal noise shielding layer to electrically insulate the metal noise shielding layer,
wherein the second insulating layer comprises a bonding oxide layer disposed at an interface between the device wafer and the carrier wafer to bond the carrier wafer to the device wafer.

7. The image sensor of claim 1, wherein the carrier wafer comprises a highly doped silicon substrate to further shield the pixel array from the noise emanating from the signal lines, wherein the carrier wafer is doped to have a linear resistance of less than 5 ohm-centimeters.

8. The image sensor of claim 7, wherein the carrier wafer is doped such that the linear resistance is less than 0.02 ohm-centimeters.

9. The image sensor of claim 1, further comprising:
metal pads disposed on the second side of the carrier wafer coupled to the signal lines; and
a low-K dielectric layer disposed between the second side of the carrier wafer and the metal pads to reduce capacitive coupling between the signal lines and the device wafer, wherein the low-K dielectric layer has a first dielectric constant less than a second dielectric constant of oxide.

10. The image sensor of claim 9, wherein the metal pads are disposed on the low-K dielectric layer without an intervening insulating layer.

11. The image sensor of claim 9, wherein the first dielectric constant of the low-K dielectric layer is less than 3.0.

12. The image sensor of claim 1, wherein the TSV comprises:
a hole extending through the carrier wafer and into the device wafer;
an insulating liner disposed on sidewalls of the hole; and
an inner metal conductor,
wherein the metal noise shielding layer includes an oversized etch gap that is wider than a portion of the TSV that passes through the metal noise shielding layer such that the insulating liner disposed on the sidewalls of the hole do not contact the metal noise shielding layer.

13. The image sensor of claim 1, wherein oversized etch gap is formed prior to bonding the carrier wafer to the device wafer.

14. A method of fabricating an image sensor, the method comprising:
forming a pixel array within a device wafer having first and second sides, the pixel array responsive to light incident on a first side of the device wafer;
bonding a first side of carrier wafer to the second side of the device wafer;
forming a metal noise shielding layer extending beneath the pixel array within at least one of the device wafer or the carrier wafer;
etching a through-silicon-via (“TSV”) extending from a second side of the carrier wafer through the carrier wafer and the metal noise shielding layer and extending into the device wafer to couple to circuitry within the device wafer;
forming signal lines adjacent to the second side of the carrier wafer,
wherein the metal noise shielding layer is formed between the pixel array and the signal lines to shield the pixel array from noise emanating from the signal lines.

15. The method of claim 14, wherein the metal noise shielding layer is formed in or on the device wafer prior to bonding the carrier wafer to the device wafer.

16. The method of claim 15, further comprising:
etching a gap in the metal noise shielding layer in a location where the TSV will extend through the metal noise shielding layer prior to bonding the carrier wafer; and
filling the gap with insulating material prior to bonding the carrier wafer to the device wafer,
wherein etching the TSV comprises etching the TSV through the insulating material in the gap without having to etch the metal noise shielding layer during the etching of the TSV.

17. The method of claim 14, wherein the metal noise shielding layer is formed in or on the carrier wafer prior to bonding the carrier wafer to the device wafer.

18. The method of claim 14, further comprising:
doped a silicon substrate of the carrier wafer to further shield the pixel array from the noise emanating from the signal lines, wherein the carrier wafer is doped to have a linear resistance of less than 5 ohm-centimeter.

19. The method of claim 14, further comprising:
forming another TSV used to bias the metal noise shielding layer.

20. The method of claim 14, further comprising:
forming metal pads disposed on the second side of the carrier wafer coupled to the signal lines; and
forming a low-K dielectric layer disposed between the second side of the carrier wafer and the metal pads to reduce capacitive coupling between the signal lines and the device wafer, wherein the low-K dielectric layer has a first dielectric constant less than a second dielectric constant of oxide.
